(19) United States
(12) Patent Application Publication
(10) Pub. No.: US 2024/0186767 A1
(43) Pub. Date: Jun. 6, 2024

(54) METHOD OF MANUFACTURING SEMICONDUCTOR OPTICAL DEVICE

(71) Applicant: Sumitomo Electric Industries, Ltd., Osaka-shi (JP)

(72) Inventors: Takehiko KIKUCHI, Osaka-shi (JP); Nobuhiko NISHIYAMA, Tokyo (JP)

(73) Assignee: Sumitomo Electric Industries, Ltd., Osaka-shi (JP)

(21) Appl. No.: 18/527,716

(22) Filed: Dec. 4, 2023

(30) Foreign Application Priority Data
Dec. 6, 2022 (JP) 2022-194942

(51) Int. Cl. H01S 5/22; H01S 5/02

(52) U.S. Cl. CPC H01S 5/22; H01S 5/0201; H01S 5/0217

(57) ABSTRACT

A method of manufacturing a semiconductor optical device having a first substrate and a chip. The method includes forming a first semiconductor layer on a second substrate, forming a second semiconductor layer on the first semiconductor layer, forming, on the second substrate, a mesa including a portion of the second semiconductor layer, cutting the second substrate to form a chip including the mesa and the second substrate, bonding the mesa of the chip to the first substrate, after the bonding, removing the second substrate by etching, and after the removing the second substrate, removing the first semiconductor layer. The etching proceeds more easily in a second direction crossing a first direction than in the first direction, and after the cutting, a length of the mesa in the first direction is equal to or less than a length of the second substrate in the first direction.

### CROSS REFERENCE TO RELATED APPLICATIONS

This application claims priority based on Japanese Patent Application No. 2022-194942 filed on Dec. 6, 2022, and the entire contents of the Japanese patent application are incorporated herein by reference.

### TECHNICAL FIELD

The present disclosure relates to a method of manufacturing a semiconductor optical device.

### BACKGROUND

There is known a technique for bonding a semiconductor device formed of a compound semiconductor and having an optical gain to a substrate such as a Silicon On Insulator (SOI) substrate (silicon photonics) in which a waveguide is formed (for example, Japanese Unexamined Patent Application Publication No. 2015-164148). For example, a semiconductor layer is grown on a wafer of the compound semiconductor such as indium phosphide (InP). The semiconductor device is formed by cutting the wafer. The semiconductor device is bonded to the SOI substrate. After the bonding, etching or the like is performed on the semiconductor device.

### SUMMARY

A method of manufacturing a semiconductor optical device according to the present disclosure is a method of manufacturing a semiconductor optical device having a first substrate and a chip including a III-V compound semiconductor. The method includes forming a first semiconductor layer on a second substrate, forming a second semiconductor layer on the first semiconductor layer, forming, on the second substrate, a mesa including a portion of the second semiconductor layer, cutting the second substrate to form a chip including the mesa and the second substrate, bonding the mesa of the chip to the first substrate, after the bonding, removing the second substrate by etching, and after the removing the second substrate, removing the first semiconductor layer. The etching in the removing the second substrate proceeds more easily in a second direction crossing a first direction than in the first direction, and after the cutting, a length of the mesa in the first direction is equal to or less than a length of the second substrate in the first direction.

### BRIEF DESCRIPTION OF THE DRAWINGS

FIG. 1A is a perspective view illustrating a semiconductor optical device according to a first embodiment.

FIG. 1B is a cross-sectional view taken along line A-A of FIG. 1A.

FIG. 2A illustrates a method of manufacturing a semiconductor optical device.

FIG. 2B illustrates a method of manufacturing a semiconductor optical device.

FIG. 3A illustrates a method of manufacturing a semiconductor optical device

FIG. 3B illustrates a method of manufacturing a semiconductor optical device.

FIG. 4A illustrates a method of manufacturing a semiconductor optical device.

FIG. 4B illustrates a method of manufacturing a semiconductor optical device.

FIG. 5A illustrates a method of manufacturing a semiconductor optical device.

FIG. 5B illustrates a method of manufacturing a semiconductor optical device.

FIG. 6A illustrates a method of manufacturing a semiconductor optical device.

FIG. 6B illustrates a method of manufacturing a semiconductor optical device.

FIG. 7A illustrates a method of manufacturing a semiconductor optical device.

FIG. 7B illustrates a method of manufacturing a semiconductor optical device.

FIG. 8A illustrates a method of manufacturing a semiconductor optical device.

FIG. 8B illustrates a method of manufacturing a semiconductor optical device.

FIG. 9A illustrates a method of manufacturing a semiconductor optical device.

FIG. 9B illustrates a method of manufacturing a semiconductor optical device.

FIG. 9C is an enlarged view of a residue.

FIG. 10A illustrates a method of manufacturing a semiconductor optical device.

FIG. 10B illustrates a method of manufacturing a semiconductor optical device.

FIG. 11A is a cross-sectional view illustrating a method of manufacturing a semiconductor optical device according to a comparative example.

FIG. 11B is a cross-sectional view illustrating a method of manufacturing a semiconductor optical device according to the comparative example.

FIG. 11C is a cross-sectional view illustrating a method of manufacturing a semiconductor optical device according to the comparative example.

FIG. 12A illustrates a method of manufacturing a semiconductor optical device.

FIG. 12B illustrates a method of manufacturing a semiconductor optical device.

FIG. 13A illustrates a method of manufacturing a semiconductor optical device.

FIG. 13B illustrates a method of manufacturing a semiconductor optical device.

FIG. 14A illustrates a method of manufacturing a semiconductor optical device.

FIG. 14B illustrates a method of manufacturing a semiconductor optical device.

FIG. 15A illustrates a method of manufacturing a semiconductor optical device.

FIG. 15B illustrates a method of manufacturing a semiconductor optical device.

FIG. 16A illustrates a method of manufacturing a semiconductor optical device.

FIG. 16B illustrates a method of manufacturing a semiconductor optical device.

FIG. 17A illustrates a method of manufacturing a semiconductor optical device.

FIG. 17B illustrates a method of manufacturing a semiconductor optical device.

FIG. 18A illustrates a method of manufacturing a semiconductor optical device.

FIG. 18B illustrates a method of manufacturing a semiconductor optical device.

FIG. 19A illustrates a method of manufacturing a semiconductor optical device.

FIG. 19B illustrates a method of manufacturing a semiconductor optical device.

FIG. 20 is a plan view illustrating a chip according to a first modification.

FIG. 21 is a plan view illustrating a chip according to a second modification.

FIG. 22 is a plan view illustrating a chip according to a third modification.

### DETAILED DESCRIPTION

In the etching after the bonding, residues may occur due to anisotropy of the etching. The residues become an obstacle to the subsequent steps such as application of a resist. Therefore, it is an object of the present disclosure to provide a method of manufacturing a semiconductor optical device capable of suppressing the influence of the etching residues.

### [Description of Embodiments of Present Disclosure]

First, the contents of embodiments of the present disclosure will be listed and explained.

(1) An embodiment of the present disclosure is a method of manufacturing a semiconductor optical device having a first substrate and a chip including a III-V compound semiconductor. The method includes forming a first semiconductor layer on a second substrate, forming a second semiconductor layer on the first semiconductor layer, forming, on the second substrate, a mesa including a portion of the second semiconductor layer, cutting the second substrate to form a chip including the mesa and the second substrate, bonding the mesa of the chip to the first substrate, after the bonding, removing the second substrate by etching, and after the removing the second substrate, removing the first semiconductor layer. The etching in the removing the second substrate proceeds more easily in a second direction crossing a first direction than in the first direction, and after the cutting, a length of the mesa in the first direction is equal to or less than a length of the second substrate in the first direction. Since the etching proceeds more easily in the second direction, the second substrate is removed by etching. Since the etching is less likely to proceed in the first direction, residues of the second substrate may occur. By removing the first semiconductor layer, the residues are also removed. Since mesa is shorter than the second substrate in the first direction, occurrence of the residues is suppressed. The influence of the etching residues on the semiconductor optical device is suppressed.

(2) In the above (1), in the forming the mesa, the mesa including the portion of the second semiconductor layer may be formed by etching another portion of the second semiconductor layer other than the portion of the second semiconductor layer, and after the cutting, the length of the mesa in the first direction may be smaller than the length of each of the second substrate and the first semiconductor layer in the first direction. In the first direction, the first semiconductor layer protrudes from the mesa to the outside. The residues of the second substrate occur in the protruding portion. By removing the first semiconductor layer, the residues of the second substrate are also removed.

(3) In the above (2), a length between an end of the second substrate and an end of the mesa in the first direction may be 1.5 times to 2 times a thickness of the second substrate. Since the length is equal to or more than 1.5 times the thickness, the residues are less likely to occur above the mesa and are located outside the mesa. By removing the first semiconductor layer, the residues are also removed. Since the length is equal to or less than 2 times the thickness, cracks are less likely to occur in the portion protruding outside the mesa.

(4) In the above (2) or (3), the second substrate and the mesa after the cutting may have a side perpendicular to the first direction and a side perpendicular to the second direction. Since the etching is less likely to proceed in the first direction, the residues occur near the side perpendicular to the first direction of the mesa. By removing the first semiconductor layer, the residues can also be removed.

(5) In the above (1), in the forming the mesa, the mesa including a portion of the first semiconductor layer and the portion of the second semiconductor layer may be formed by etching another portion of the first semiconductor layer and another portion of the second semiconductor layer other than the portion of the first semiconductor layer and the portion of the second semiconductor layer, and the mesa may have no side perpendicular to the first direction. In the etching of the second substrate, occurrence of the residues is suppressed.

(6) In the above (5), a planar shape of the mesa may be a polygonal shape or a shape including a curved line. As the etching proceeds in the second direction, the second substrate is removed. Occurrence of the residues is suppressed.

(7) In the above (5) or (6), the mesa may have a side inclined from the second direction. As the etching proceeds in the second direction, the second substrate is removed. Occurrence of the residues is suppressed.

(8) In any one of (1) to (7), the second substrate may include indium phosphide, and the first semiconductor layer may include indium gallium arsenide. A high etching selectivity can be obtained between the second substrate and the first semiconductor layer. The second substrate is removed by etching. The etching stops at the first semiconductor layer.

(9) In the above (8), in the removing the second substrate, the second substrate may be removed by wet etching using hydrochloric acid as an etchant. The high etching selectivity can be obtained between the second substrate and the first semiconductor layer. The second substrate is removed by etching. The etching stops at the first semiconductor layer.

(10) In any one of (1) to (9), the method may include, after the removing the first semiconductor layer, etching the portion of the second semiconductor layer. The influence of the residues on the processing of the portion of the second semiconductor layer is suppressed.

### [Details of Embodiments of Present Disclosure]

Specific examples of a method of manufacturing a semiconductor optical device according to the embodiments of the present disclosure will be described below with reference to the drawings. The present disclosure is not limited to these examples, and is defined by the scope of the claims, and is intended to include all modifications within the meaning and scope equivalent to the scope of the claims.

### First Embodiment

### (Semiconductor Optical Device)

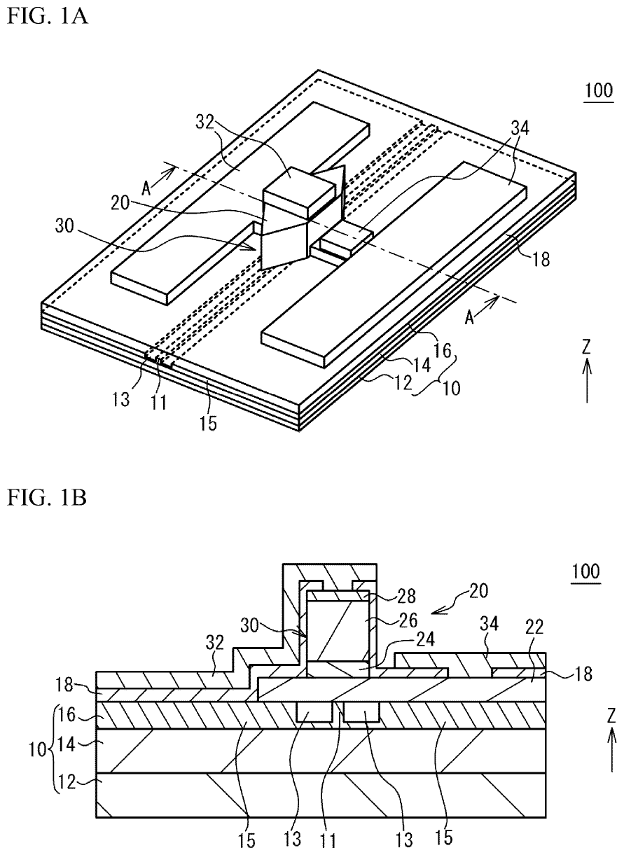

FIG. 1A is a perspective view illustrating a semiconductor optical device 100 according to a first embodiment. FIG. 1B is a cross-sectional view taken along line A-A of FIG. 1A. As illustrated in FIGS. 1A and 1B, semiconductor optical device 100 is a hybrid laser device having a substrate 10 (first substrate) and a semiconductor device 20. Semiconductor device 20 is a device including a III-V compound semiconductor layer. Semiconductor device 20 has, for example, an optical gain and generates light. In another example, semiconductor device 20 is light sensitive and absorbs light to generate a photocurrent. Semiconductor device 20 may modulate light by changing a refractive index according to a voltage. Substrate 10 propagates light. A Z-axis direction is a normal direction of a top surface of substrate 10.

As illustrated in FIG. 1B, substrate 10 is an SOI substrate including a substrate 12, a box layer 14, and a silicon (Si) layer 16 that are sequentially stacked in the Z-axis direction. Substrate 12 is formed of, for example, Si. Box layer 14 is formed of, for example, silicon oxide (SiO₂). A thickness of box layer 14 is, for example, 3 μm. A thickness of Si layer 16 is, for example, 220 nm. The top surface of substrate 10 is covered by an insulating film 18. Insulating film 18 is formed of, for example, SiO₂ having a thickness of 1 μm. A refractive index of Si layer 16 is 3.45. A refractive index of each of box layer 14 and insulating film 18 is 1.45, which is lower than the refractive index of Si layer 16.

Si layer 16 of substrate 10 has a waveguide 11, two recesses 13, and two terraces 15. Waveguide 11 and recess 13 extend in the same direction. Two recesses 13 are located on both sides of waveguide 11 and extend in the same direction as waveguide 11. Terrace 15 is a plane of Si layer 16 and is located opposite to waveguide 11 with respect to recess 13. Although a bottom surface of recess 13 is Si layer 16 in FIG. 1B, the bottom surface may be box layer 14. Si layer 16 may be provided with optical components such as a ring resonator and a loop mirror. For example, the ring resonator is formed by bending waveguide 11 in a ring shape.

As illustrated in FIG. 1B, semiconductor device 20 is bonded to a top surface of Si layer 16 on waveguide 11 and recesses 13. Semiconductor device 20 includes a cladding layer 22, an active layer 24, a cladding layer 26, and a contact layer 28. Cladding layer 22 to contact layer 28 are sequentially stacked upward from the top surface of substrate 10.

Cladding layer 22 is formed of, for example, n-type indium phosphide (n-InP) having a thickness of 400 nm. Cladding layer 26 is formed of, for example, p-InP having a thickness of 2 μm. Contact layer 28 is formed of, for example, (p+)-gallium indium arsenide (GaInAs). Active layer 24 includes a plurality of well layers and barrier layers alternately stacked, and has a multi-quantum well (MQW) structure. The well layers and the barrier layers are formed of, for example, non-doped gallium indium arsenide phosphide (i-GaInAsP). A thickness of active layer 24 is, for example, 300 nm. Active layer 24 has an optical gain and emits light having a wavelength of 1.55 μm, for example. Each layer of semiconductor device 20 may be formed of a III-V compound semiconductor other than those described above.

As illustrated in FIG. 1A, semiconductor device 20 has a mesa 30 and electrodes 32 and 34. Mesa 30 of semiconductor device 20 is located above waveguide 11. A tip of mesa 30 has a tapered shape and is tapered along waveguide 11. Mesa 30 and the tapered tip of semiconductor device 20 or the like are the element structure.

As illustrated in FIG. 1B, mesa 30 is formed of active layer 24, cladding layer 26, and contact layer 28 and located above waveguide 11. Cladding layer 22 is located between mesa 30 and substrate 10 and extends to the outside of mesa 30. Cladding layer 22 is in contact with the top surface of waveguide 11 and the top surface of terrace 15 of substrate 10. Mesa 30 and a front surface of cladding layer 22 are covered by insulating film 18. Insulating film 18 has openings in mesa 30 and in cladding layer 22.

As illustrated in FIG. 1B, electrode 32 extends from a top of mesa 30 to a top surface of insulating film 18 on the outside of mesa 30. Electrode 32 is electrically connected to contact layer 28 through the opening in insulating film 18. Electrode 32 is formed of, for example, a stack of titanium, platinum, and gold (Ti/Pt/Au). Electrode 34 is spaced apart from electrode 32, disposed on a top surface of insulating film 18, and electrically connected to cladding layer 22 through the opening in insulating film 18. Electrode 34 is formed of metal such as an alloy of gold, germanium, and nickel (AuGeNi). A plating layer of Au or the like may be provided on electrode 32 and electrode 34.

A voltage is applied to electrodes 32 and 34 to inject carriers into active layer 24 of semiconductor device 20. By injecting carriers, active layer 24 generates light. Semiconductor device 20 and substrate 10 are evanescently optically coupled to each other, and the light transits to waveguide 11 of substrate 10. The light propagates through waveguide 11 and is emitted from ends of substrate 10 to the outside of semiconductor optical device 100.

### (Method of Manufacturing)

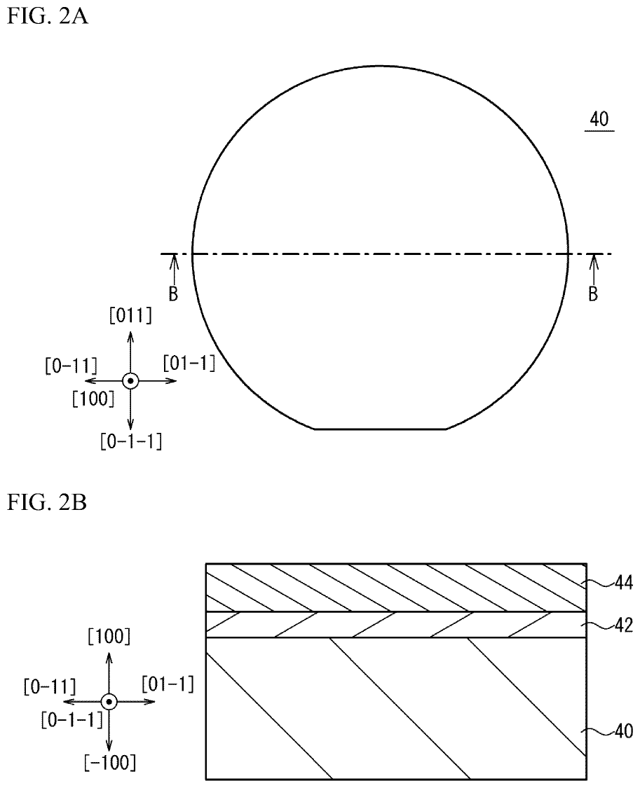

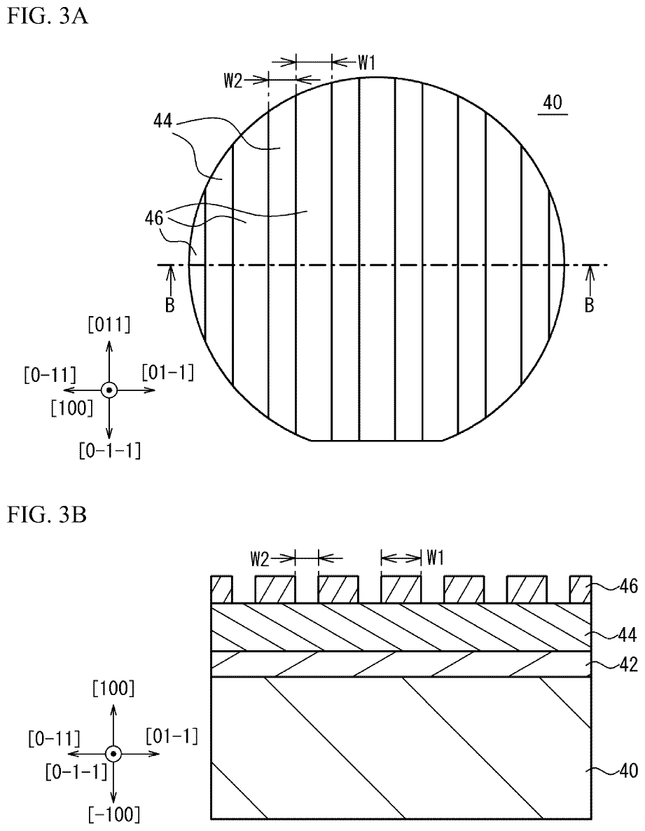

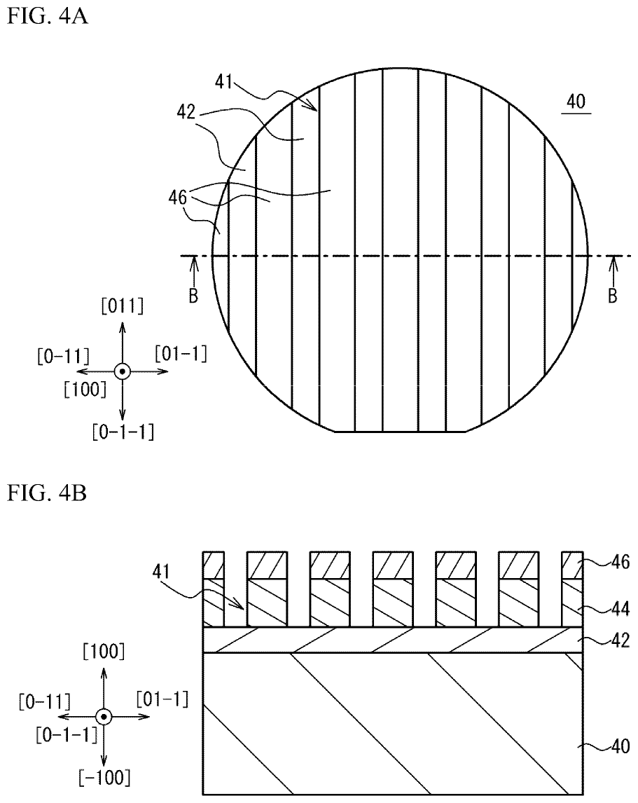

FIGS. 2A to 10B illustrate a method of manufacturing semiconductor optical device 100. FIGS. 2A, 3A, and 4A are plan views illustrating a substrate 40 (second substrate). FIG. 2B, FIG. 3B and FIG. 4B are cross-sectional views along line B-B of the corresponding plan views, respectively. In the drawings, directions of the crystal of substrate 40 are illustrated. In FIG. 2A, a front surface of substrate 40 is a (100) plane. A direction from the back to the front of substrate 40 is a [100] direction. An upward direction of the substrate 40 is a direction. A downward direction of the substrate 40 is a [0-1-1] direction. A rightward direction of the substrate 40 is a [01-1] direction. A leftward direction of the substrate 40 is a [0-11] direction. The [0-11] direction and the [01-1] direction correspond to a first direction. The direction and the [0-1-1] direction correspond to a second direction.

Substrate 40 illustrated in FIG. 2A is, for example, a 2-inch InP substrate. As illustrated in FIG. 2B, an etching stop layer 42 (first semiconductor layer) and a semiconductor layer 44 (second semiconductor layer) are epitaxially grown in this order on one surface of substrate 40 by, for example, Metalorganic Vapor Phase Epitaxy (MOVPE) method. Semiconductor layer 44 includes cladding layer 22, active layer 24, cladding layer 26, and contact layer 28 illustrated in FIG. 1B. On etching stop layer 42, cladding layer 22, active layer 24, cladding layer 26, and contact layer 28 are stacked in this order. Substrate 40 is formed of, for example, indium phosphide (InP) having a thickness of 350 μm. Etching stop layer 42 is formed of, for example, indium gallium arsenide (InGaAs) having a thickness of 0.3 μm.

As illustrated in FIGS. 3A and 3B, masks 46 are formed on a top surface of semiconductor layer 44 by, for example, Plasma Chemical Vapor Deposition (CVD) method. Mask 46 is formed of an insulating material such as silicon oxide (SiO₂). A thickness of mask 46 is 0.3 μm, for example. Mask 46 extends in the direction and the [0-1-1] direction and are provided from one end of the InP substrate to the other end. A plurality of masks 46 are periodically arranged between the [0-11] direction and the [01-1] direction. As illustrated in FIG. 3A, the plurality of masks 46 are provided in stripe pattern. Semiconductor layer 44 is exposed between two masks 46. A width W1 of mask 46 is, for example, 2.0 mm. A width W2 of semiconductor layer 44 exposed from mask 46 is, for example, 1.2 mm.

As illustrated in FIGS. 4A and 4B, etching is performed using masks 46 to form mesas 41. The portions of semiconductor layer 44 exposed from masks 46 are removed by the etching. For example, 90% of the thickness of semiconductor layer 44 is removed by dry etching, and 10% of the thickness is removed by wet etching. After the etching, etching stop layer 42 is exposed between masks 46. Semiconductor layer 44 remains under masks 46 to form mesas 41.

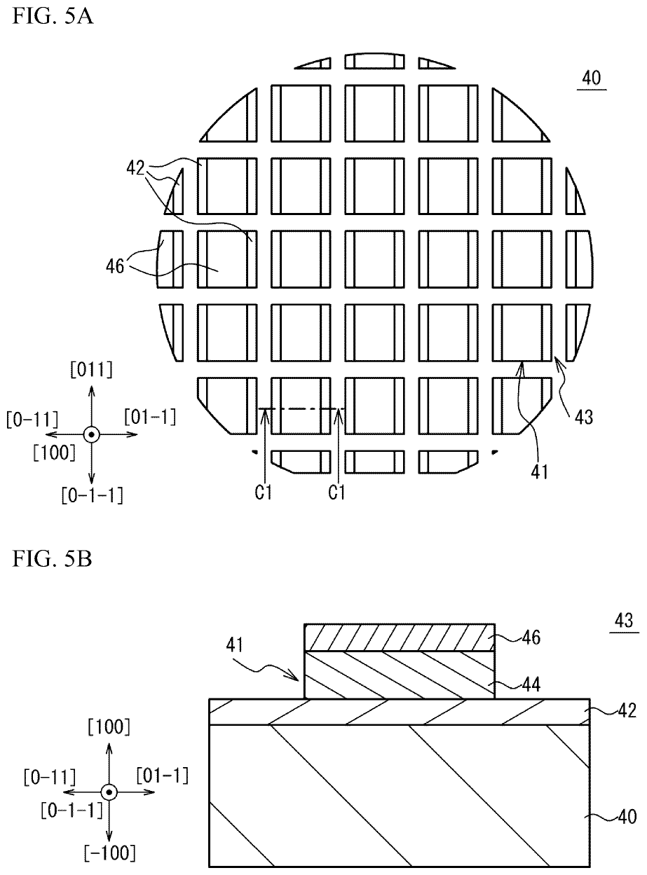

FIG. 5A is a plan view illustrating substrate 40 after dicing. FIG. 5B is a cross-sectional view along line C1-C1 of FIG. 5A, illustrating a cross section including one chip 43. InP is prone to crack along the [0-11] direction and the [0-1-1] direction. A wafer is divided along these directions. As illustrated in FIG. 5A, the wafer is divided by dicing to form a plurality of chips 43. Etching stop layer 42 and substrate 40 between masks 46 are cut along the direction and the [0-1-1] direction. Mask 46, semiconductor layer 44, etching stop layer 42, and substrate 40 are cut along the [0-11] direction and the [01-1] direction. Chips 43 are formed by the dicing. As illustrated in FIG. 5B, chip 43 includes substrate 40, etching stop layer 42 and semiconductor layer 44. When the section of chip 43 is viewed from the direction, mesa 41 is located substantially at the center of chip 43. Chip 43 includes a semiconductor layer formed of III-V compound and is bonded to substrate 10. Semiconductor device 20 of FIGS. 1A and 1B is formed by processing chip 43 after the bonding.

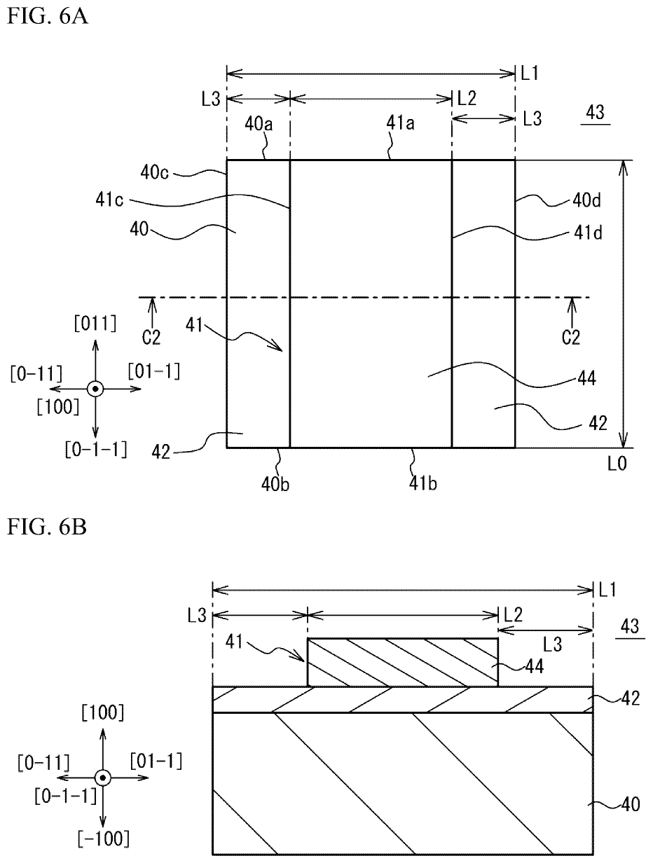

FIG. 6A is a plan view illustrating one chip 43. FIG. 6B is a cross-sectional view taken along line C2-C2 of FIG. 6A. As illustrated in FIGS. 6A and 6B, after the dicing, mask 46 is removed by etching using buffered hydrofluoric acid. A front surface of semiconductor layer 44 is exposed.

As illustrated in FIG. 6A, a planar shape of mesa 41 and chip 43 is rectangular. Substrate 40 has a side 40a perpendicular to the direction, a side 40b perpendicular to the [0-1-1] direction, a side 40c perpendicular to the [0-11] direction, and a side 40d perpendicular to the [01-1] direction. Mesa 41 has a side 41a perpendicular to the direction, a side 41b perpendicular to the [0-1-1] direction, a side 41c perpendicular to the [0-11] direction, and a side 41d perpendicular to the [01-1] direction. In a plan view, side 41a overlaps side 40a. Side 41b overlaps side 40b. Side 41c and side 41d are spaced apart from side 40c and side 40d, and are located inside side 40c and side 40d, respectively.

A length L1 of side 40a of chip 43 is, for example, 3.2 mm. A length L0 of side 40d of chip 43 is, for example, 3.2 mm. Length L1 may be equal to length L0 or may be different from length L0. The length of the direction and the [0-1-1] direction of mesa 41 is equal to length L0 of chip 43. A length L2 of the [0-11] direction and the [01-1] direction of mesa 41 is equal to a width W1 of mask 46, for example, 2.0 mm. Length L2 of mesa 41 is smaller than length L1 of chip 43. Etching stop layer 42 is exposed on the outside of mesa 41 in the [0-11] direction and the outside of mesa 41 in the [01-1] direction. A length L3 of the exposed portion of etching stop layer 42 is, for example, 0.6 mm.

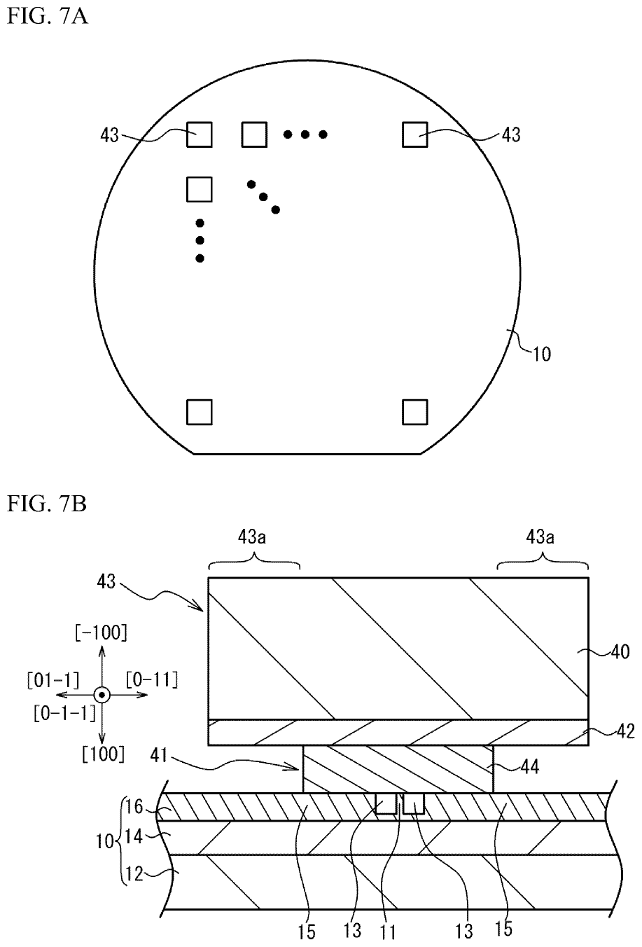

FIG. 7A is a plan view illustrating substrate 10. Substrate 10 is, for example, a wafer having a diameter of 10 inches. As illustrated in FIG. 7A, a plurality of chips 43 are bonded to substrate 10. The bonding method is hydrophilic bonding or plasma activated bonding. A front surface of mesa 41 and a front surface of Si layer 16 of substrate 10 are hydrophilized or activated by plasma irradiation.

FIG. 7B is a cross-sectional view illustrating a drawing including one chip 43. As illustrated in FIG. 7B, the front surface of mesa 41 is opposed to and brought into contact with the front surface of Si layer 16 of substrate 10. After the contact, heat treatment is performed at a temperature of, for example, 300° C. to increase the bonding strength. Substrate 40 of chip 43 is located opposite to substrate 10 with mesa 41 interposed therebetween. As illustrated in FIG. 7B, semiconductor layer 44 is bonded onto waveguide 11 of substrate 10. Portions of substrate 40 and etching stop layer 42 protrude to the outside of mesa 41. The protruding portion is referred to as an overhanging portion 43a.

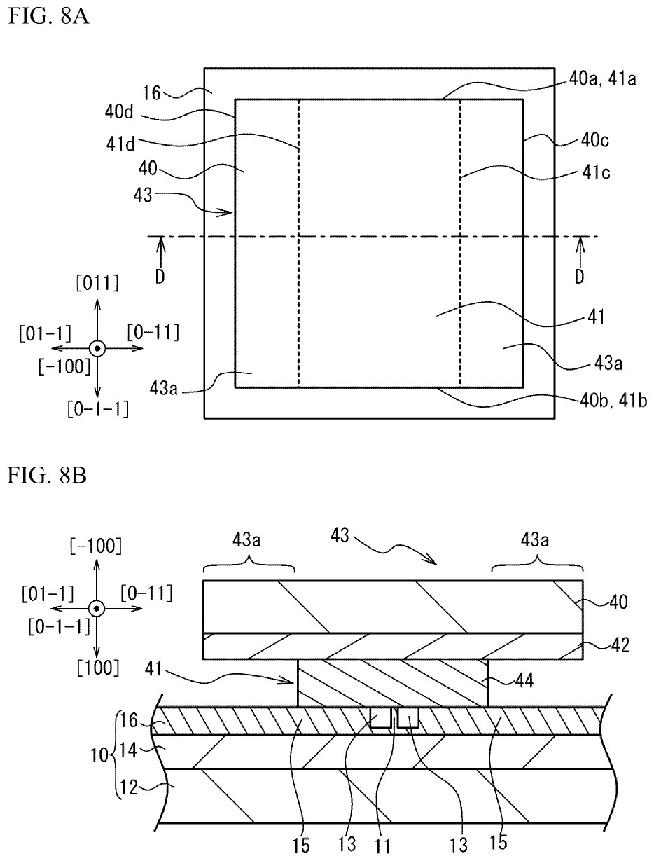

FIGS. 8A, 9A and 10A are plan views illustrating a plane including one chip. FIGS. 8B, 9B and 10B are cross-sectional views along line D-D of the corresponding plan views. As illustrated in FIG. 8B, after chip 43 is bonded, substrate 40 is subjected to chemical mechanical polishing (CMP) to set the thickness of substrate 40 to, for example, 80 μm.

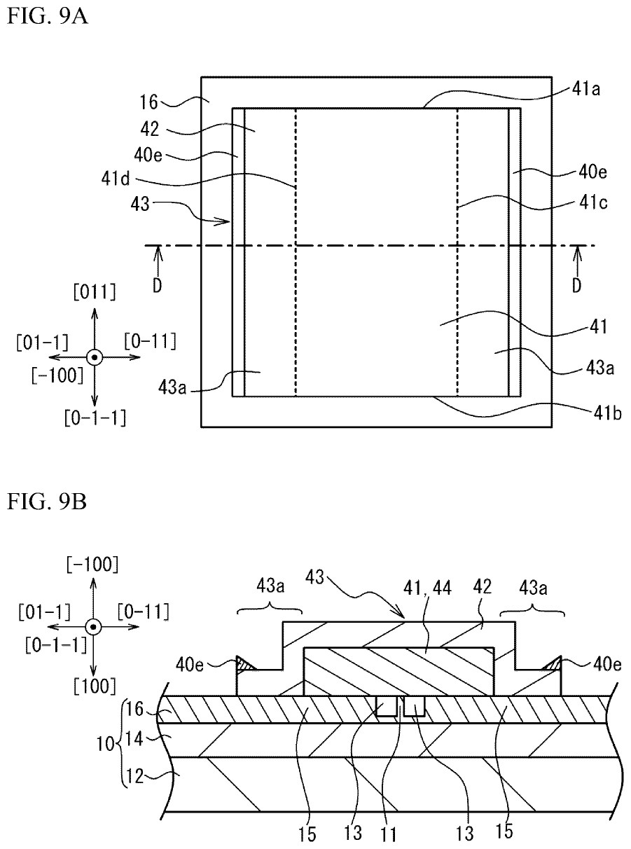

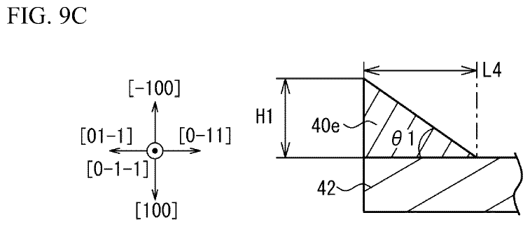

As illustrated in FIGS. 9A and 9B, wet etching is performed from the back surface of substrate 40 to remove substrate 40 of chip 43. The wet etching stops at etching stop layer 42. When substrate 40 is an InP substrate, a back surface of substrate 40 is a (−100) plane. When substrate 40 is the InP substrate, a solution containing hydrochloric acid (HCl) is used as the etchant. The etchant solution is selected according to the material constituting substrate 40. After the wet etching, overhanging portions 43a hang down by its own weight. Etching stop layer 42 covers the side surfaces of semiconductor layer 44 and contacts the top surface of substrate 10, but is not bonded to substrate 10.

The wet etching of substrate 40 has anisotropy. When wet etching is performed on the (−100) plane of the InP substrate using a hydrochloric acid-based etchant, the etching proceeds in the thickness direction of substrate 40, i.e., the direction. At the same time, the etching also proceeds in the [01-1] direction, the [0-11] direction, the direction, and the [0-1-1] direction. The wet etching proceeds three dimensionally in all directions. The ease with which etching proceeds varies from direction to direction. An etching rate in a direction perpendicular to a plane having an angle of 35 degrees with respect to the (−100) plane is very small, and the etching hardly proceeds in this direction. The time from the start of the wet etching of substrate 40 until substrate 40 melts away in a certain direction is defined as the etching rate in that direction. The etching rate in the [01-1] direction and the etching rate in the [0-11] direction are less than the etching rate in the direction and the etching rate in the [0-1-1] direction. Due to the anisotropy of the etching, the etching residues may occur.

The etching proceeds more easily in the direction and the [0-1-1] direction. The etching proceeds to side 40a and side 40b of substrate 40, and substrate 40 is removed. On the other hand, when the etching proceeds in the [01-1] direction and the [0-11] direction, a specific crystal plane having an angle of 35 degrees with respect to the (−100) plane and extending parallel to the direction is likely to be exposed. The etching rate in the direction perpendicular to the plane inclined at 35 degrees with respect to the (−100) plane is extremely small. When the plane inclined at an angle of 35 degrees is exposed, the etching is less likely to proceed in a direction perpendicular to the plane. Compared to the direction and the [0-1-1] direction, the etching is less likely to proceed in the [01-1] direction and the [0-11] direction. In the [01-1] direction and the [0-11] direction, portions of substrate 40 remain unremoved. Etching residues 40e occur on overhanging portions 43a. As illustrated in FIG. 9A, residues 40e each extend along side 41c and side 41d.

FIG. 9C is an enlarged view of residue 40e. As illustrated in FIGS. 9B and 9C, residue 40e protrudes upward from a top surface of etching stop layer 42. A cross section shape of residue 40e is a triangle. A base angle θ1 of residue 40e is, for example, 35 degrees. A height H1 of residue 40e is, for example, 20 μm. A length L4 of residue 40e is, for example, 30 μm.

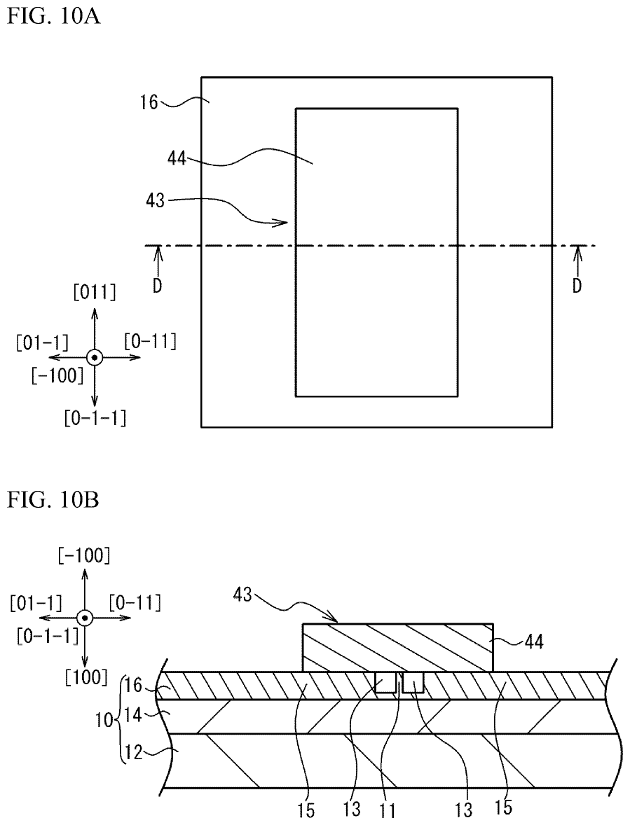

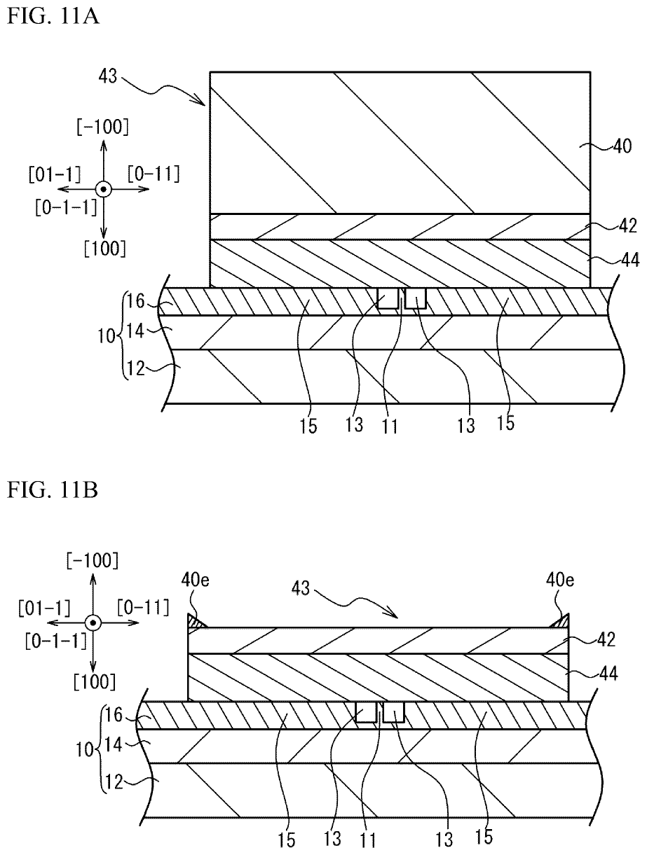

As illustrated in FIGS. 10A and 10B, etching stop layer 42 is removed by, for example, wet etching. Residues 40e are removed together with etching stop layer 42. In detail, as overhanging portions 43a of etching stop layer 42 are etched, residues 40e are separated from substrate 10 and semiconductor layer 44. After the etching, semiconductor layer 44 remains on substrate 10.

The subsequent steps are performed on semiconductor layer 44. For example, a resist pattern, etching masks and the like are provided on or above semiconductor layer 44. Etching is performed to form semiconductor device 20 illustrated in FIGS. 1A and 1B from semiconductor layer 44.

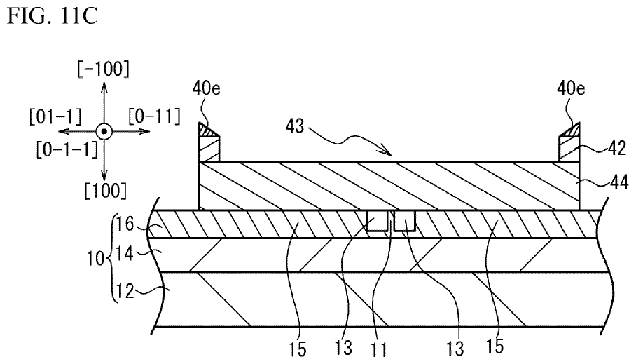

FIGS. 11A to 11C are cross-sectional views illustrating a method of manufacturing a semiconductor optical device according to a comparative example, illustrating steps after bonding chip 43. Chip 43 has no mesa 41 and no overhanging portion 43a. Substrate 40, etching stop layer 42 and semiconductor layer 44 have the same length. After the bonding, wet etching of substrate 40 is performed. As illustrated in FIG. 11B, residues 40e remain on etching stop layer 42. As illustrated in FIG. 11C, even when etching stop layer 42 is etched, residues 40e and underlying etching stop layers 42 remain. Due to the presence of residues 40e, it is difficult to form a resist pattern and etching masks on semiconductor layer 44.

According to the first embodiment, as illustrated in FIGS. 4A and 4B, mesa 41 of semiconductor layer 44 is formed on substrate 40. Chip 43 is formed by dicing. As illustrated in FIG. 6B, in chip 43, length L2 of mesa 41 along the [0-11] direction and the [01-1] direction is smaller than length L1 of substrate 40 and etching stop layer 42. After chip 43 is bonded to substrate 10, substrate 40 is removed by etching. In the etching in the [0-11] direction and the [01-1] direction, a plane having a small etching rate is likely to be exposed. The Etching proceeds more easily in the direction and the [0-1-1] direction, and is less likely to proceed in the [0-11] direction and the [01-1] direction. In the etching, residues 40e of substrate 40 remain as illustrated in FIGS. 9A and 9B. Since length L2 of mesa 41 is smaller than length L1 of substrate 40, residues 40e are located on the outside of mesa 41. By removing etching stop layer 42, residues 40e are also removed. It is possible to suppress the influence of residues 40e on the manufacturing of semiconductor optical device 100.

As illustrated in FIGS. 4A and 4B, mesa 41 is formed by etching semiconductor layer 44. The etching stops at a front surface of etching stop layer 42. As illustrated in FIG. 6B, mesa 41 is formed of semiconductor layer 44. Length L2 of mesa 41 is smaller than length L1 of substrate 40 and etching stop layer 42. Substrate 40 and etching stop layer 42 are located under mesa 41 and extend to the outside of mesa 41. As illustrated in FIG. 9B, after substrate 40 is removed, portions of etching stop layer 42 become overhanging portions 43a. Residues 40e are formed on overhanging portions 43a. By removing etching stop layer 42, residues 40e can be removed together with etching stop layer 42.

Length L3 between the end of substrate 40 and the end of mesa 41 may be 1.5 times to 2 times the thickness of substrate 40 before polishing. When length L3 is too small, residues 40e are located directly above mesa 41. Also in the etching of etching stop layer 42, residues 40e may remain above mesa 41. When length L3 is too large, cracks may occur in etching stop layer 42. By setting length L3 equal to or more than 1.5 times the thickness of substrate 40, residues 40e are located at the outside of mesa 41. By setting length L3 equal to or less than 2 times the thickness, cracking of etching stop layer 42 is suppressed. Residues 40e can also be removed by etching stop layer 42.

As illustrated in FIG. 6A, substrate 40 has side 40a perpendicular to the direction, side 40b perpendicular to the [0-1-1] direction, side 40c perpendicular to the [0-11] direction, and side 40d perpendicular to the [01-1] direction. Mesa 41 has side 41a perpendicular to the direction, side 41b perpendicular to the [0-1-1] direction, side 41c perpendicular to the [0-11] direction, and side 41d perpendicular to the [01-1] direction. In etching in the direction and the [0-1-1] direction, a plane having a small etching rate is less likely to be exposed. Since the etching rate is high, wet etching proceeds to side 40a and side 40b. Residues are less likely to occur on side 41a and side 41b.

On the other hand, in the etching in the [0-11] direction and the [01-1] direction, a plane having a small etching rate is likely to be exposed. Since the etching rate is low, wet etching is less likely to proceed to side 40c and side 40d. Residues 40e occur in the vicinity of side 40c and side 40d in substrate 40. Since length L2 of mesa 41 is smaller than length L1 of substrate 40, residues 40e are not located on side 41c and side 41d, but are located on the outside of the side. Residues 40e can be removed by etching stop layer 42.

Since the etching selectivity between substrate 40 and etching stop layer 42 is high, substrate 40 can be removed by wet etching after bonding. For example, substrate 40 is formed of InP. Etching stop layer 42 is formed of InGaAs. Hydrochloric acid is used as an etchant for the wet etching. Substrate 40 can be removed and the wet etching can be stopped at etching stop layer 42. Substrate 40 may include InP or may be formed of a semiconductor other than InP. Etching stop layer 42 may include InGaAs or may be formed of a semiconductor other than InGaAs. The etchant may contain a solution other than hydrochloric acid.

By removing residues 40e, a resist pattern, etching masks, and the like can be formed on semiconductor layer 44. Etching of semiconductor layer 44 may be performed to form mesa 30 having a tapered shape as illustrated in FIG. 1A.

The front surface of substrate 40 is assumed to be the (100) plane. The plane orientation of the front surface of substrate 40 may be inclined by 15° or less, such as 2°, 6°, or 15°, with respect to the (100) plane of InP. Even when such substrate 40 is used, the same effect as that of the first embodiment can be obtained. The first direction and the second direction may deviate from the [01-1] direction and the direction within a range of manufacturing variation. Even when the variation occurs, the same effect can be obtained.

### Second Embodiment

Also in the second embodiment, semiconductor optical device 100 is formed. Description of the same configurations as that of the first embodiment will be omitted.

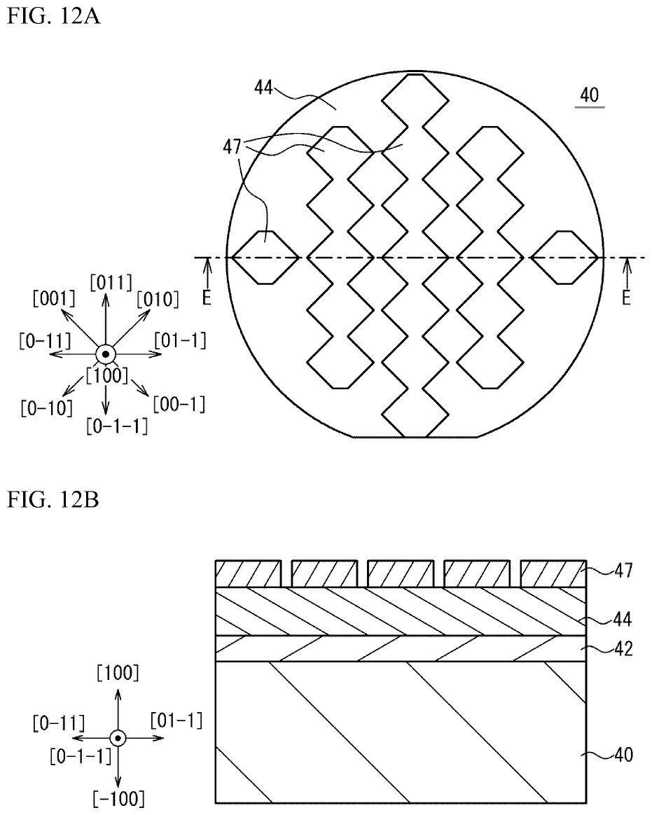

FIGS. 12A-19B illustrate a method of manufacturing semiconductor optical device 100. FIGS. 12A, 13A, and 14A are plan views illustrating substrate 40. FIGS. 12B, 13B and FIG. 14B are cross-sectional views along line E-E of the corresponding plan view.

Etching stop layer 42 and semiconductor layer 44 are epitaxially grown on or above substrate 40. As illustrated in FIGS. 12A and 12B, after the epitaxial growth, masks 47 are provided on the top surface of semiconductor layer 44. A portion of semiconductor layer 44 where mask 47 are not provided is exposed.

As illustrated in FIG. 12A, a planar shape of each of masks 47 is a polygonal shape. Mask 47 has no side perpendicular to the [0-11] direction and no side perpendicular to the [01-1] direction. Mask 47 has a side perpendicular to the direction and a side perpendicular to the [0-1-1] direction. Mask 47 has a side perpendicular to the direction, a side perpendicular to the [00-1] direction, a side perpendicular to the [0-10] direction, and a side perpendicular to the direction.

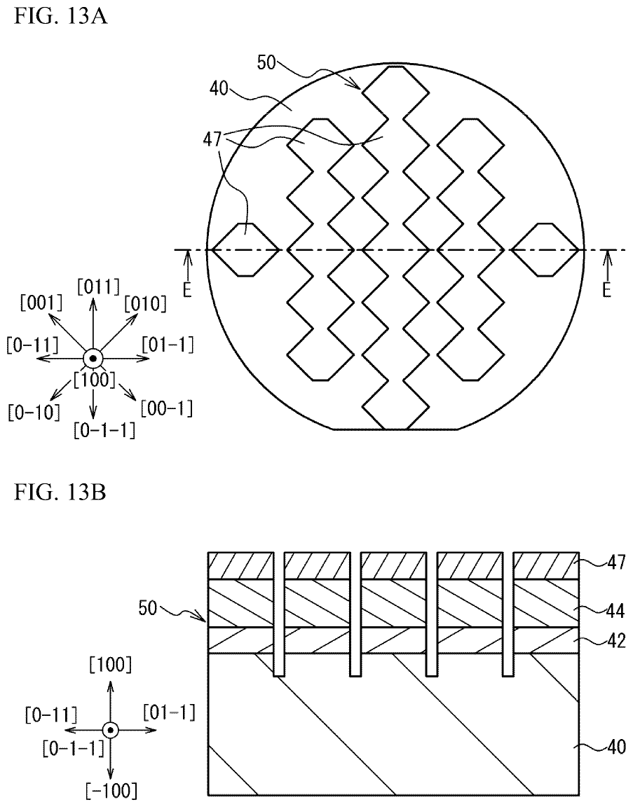

As illustrated in FIGS. 13A and 13B, etching using masks 47 is performed to form mesas 50. The etching extends through semiconductor layer 44 and etching stop layer 42, and proceeds to a position at a depth of about 1 μm from an interface between substrate 40 and etching stop layer 42 in substrate 40. After the etching, substrate 40 is exposed between masks 47. Under mask 47, semiconductor layer 44 and etching stop layer 42 remain. A portion of substrate 40, etching stop layer 42, and semiconductor layer 44 form mesa 50.

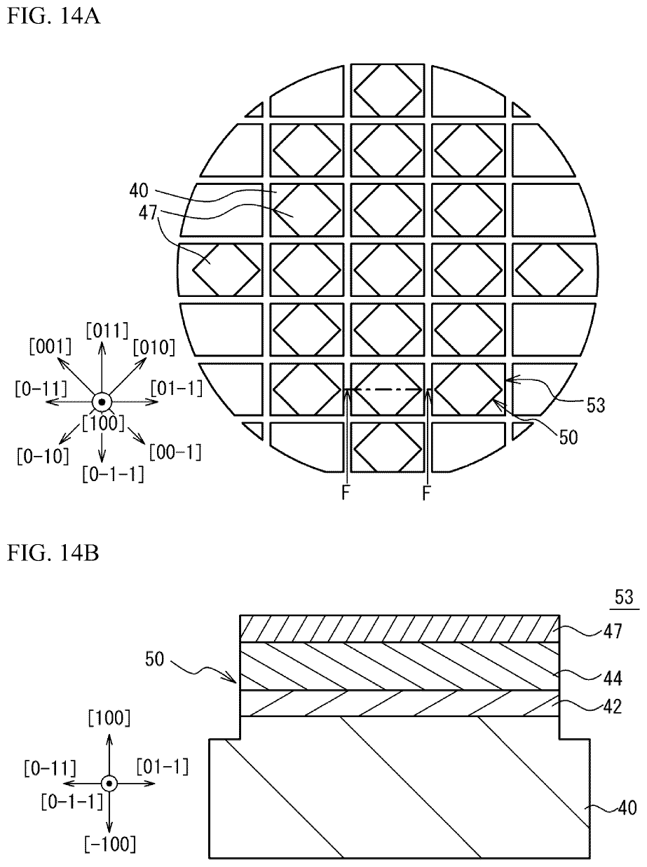

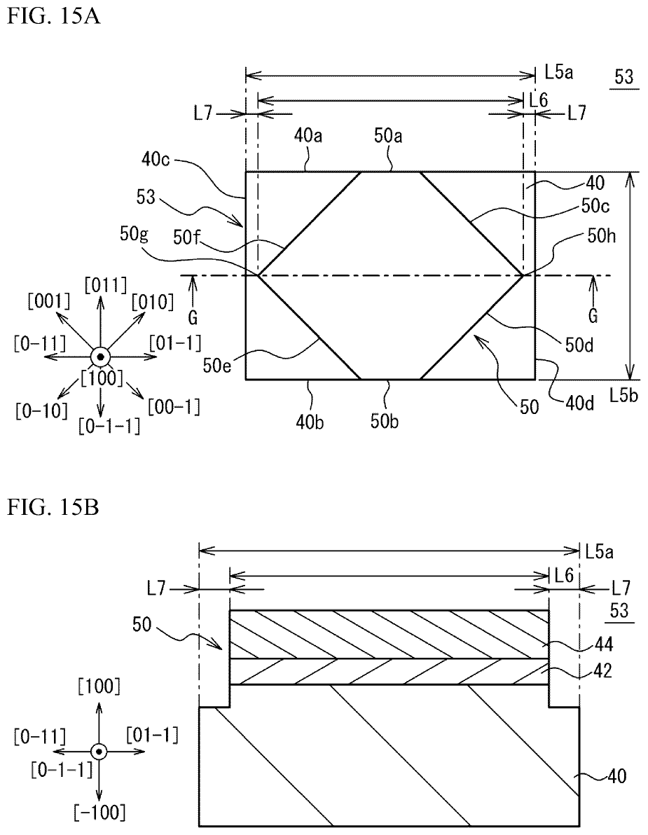

FIG. 14A and FIG. 15A are cross-sectional views illustrating substrate 40 after dicing. FIG. 14B is a cross-sectional view along line F-F of FIG. 14A, illustrating a section containing one chip 53. FIG. 15B is a cross-sectional view taken along line G-G of FIG. 15A.

As illustrated in FIG. 14A, a wafer is divided by dicing to form a plurality of chips 53. Substrate 40 between masks 47 is cut along the direction and the [0-1-1] direction. Mask 47, semiconductor layer 44, etching stop layer 42, and substrate 40 are cut along the [0-11] direction and the [01-1] direction. Chip 53 is formed by the dicing. As illustrated in FIG. 14B, chip 53 includes substrate 40, etching stop layer 42 and semiconductor layer 44. Mesa 50 is located at the center of chip 53.

As illustrated in FIGS. 15A and 15B, mask 47 is removed after the dicing. The front surface of semiconductor layer 44 is exposed. As illustrated in FIG. 15A, a planar shape of chip 53 is rectangular. A length L5a of one side of chip 53 in the [01-1] direction and the [0-11] direction is, for example, 10 mm. A length L5b of one side of chip 53 in the direction and the [0-1-1] direction is, for example, 7 mm. Substrate 40 of chip 53 has side 40a perpendicular to the direction, side 40b perpendicular to the [0-1-1] direction, side 40c perpendicular to the [0-11] direction, and side 40d perpendicular to the [01-1] direction.

As illustrated in FIG. 15A, a planar shape of mesa 50 is hexagonal. Mesa 50 has a side 50a perpendicular to the direction and a side 50b perpendicular to the [0-1-1] direction. Mesa 50 has a side 50c perpendicular to the direction, a side 50d perpendicular to the [00-1] direction, a side 50e perpendicular to the [0-10] direction, and a side 50f perpendicular to the direction. Mesa 50 has no side perpendicular to the [0-11] direction and no side perpendicular to the [01-1] direction. A vertex 50g of mesa 50 is oriented in the [0-11] direction. Vertex 50g is spaced apart from side 40c of substrate 40 and is located inside side 40c. A vertex 50h is oriented in the [01-1] direction. Vertex 50h is spaced apart from side 40d and located inside side 40d. An angle (interior angle) of each of vertex 50g between sides 50f and 50e and vertex 50h between sides 50c and 50d is, for example, 90°. A length L6 of mesa 50 from vertex 50g to vertex 50h is, for example, 9 mm. A length L7 between the end (vertex) of mesa 50 and the end of chip 53 is, for example, 0.5 mm.

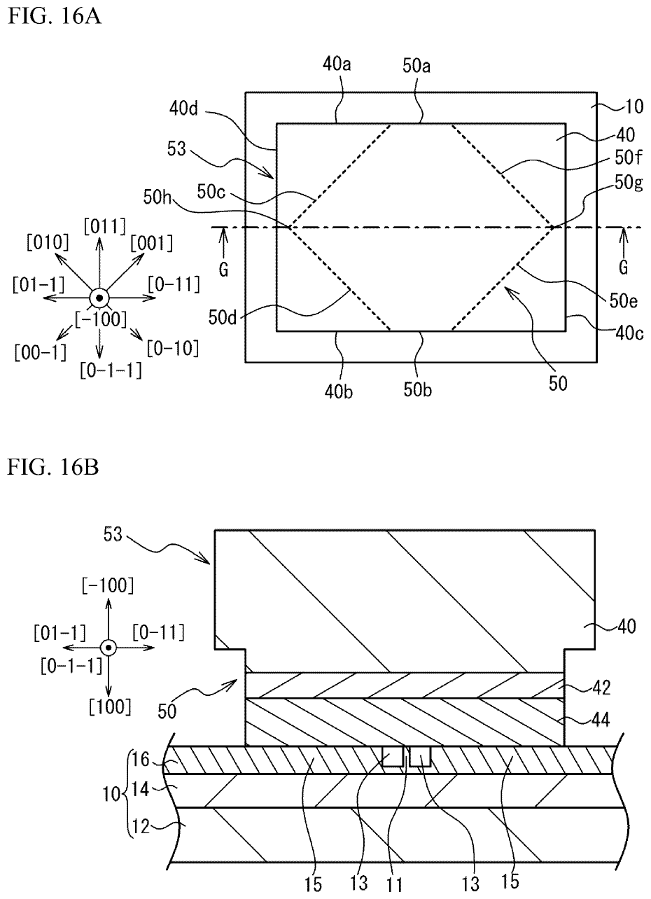

As in FIG. 7A, the plurality of chips 53 are bonded to the top surface of substrate 10. FIGS. 16A, 17A, 18A and 19A are plan views illustrating a plane including one chip. FIGS. 16B, 17B, 18B, and 19B are cross-sectional views along line G-G of the corresponding plan views.

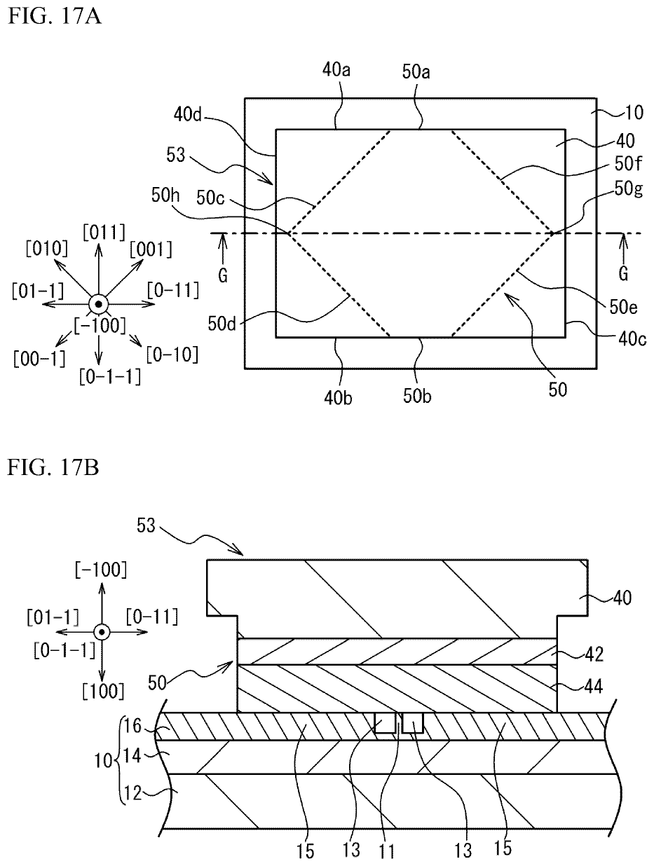

As illustrated in FIGS. 16A and 16B, semiconductor layer 44 is bonded onto waveguide 11 of substrate 10. Substrate 40 is located opposite to substrate 10 with mesa 50 interposed therebetween as illustrated in FIGS. 17A and 17B, after chip 53 is bonded, substrate 40 is polished.

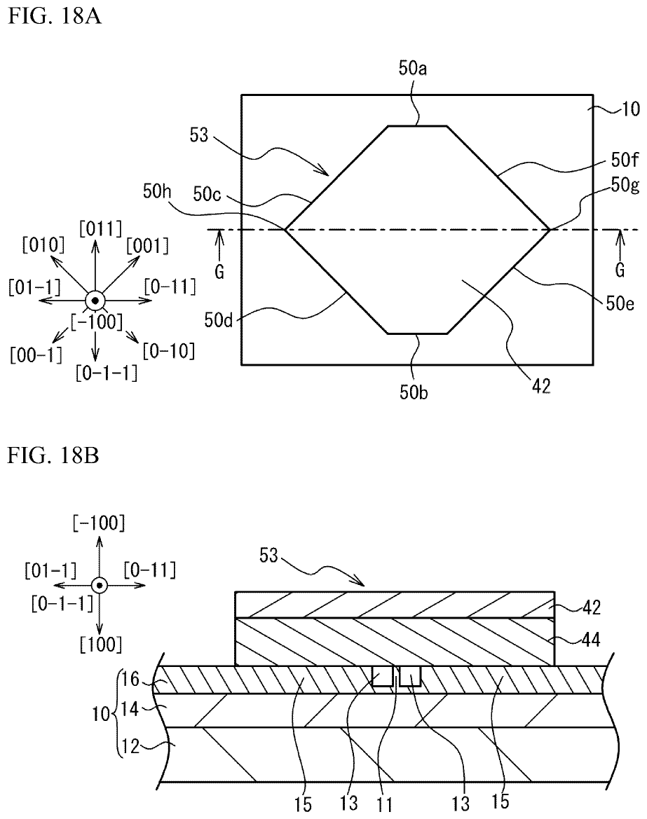

As illustrated in FIGS. 18A and 18B, wet etching is performed to remove substrate 40 of chip 53. The wet etching is stopped at etching stop layer 42.

In the etching proceeding in the direction and the [0-1-1] direction of substrate 40, a surface having a small etching rate is less likely to be exposed. That is, the etching rate is high. In the etching proceeding in the [01-1] direction and the [0-11] direction, a surface having a small etching rate is likely to be exposed. That is, the etching rate is low. The wet etching proceeds from the back surface of substrate 40 in the direction of substrate 40, simultaneously proceeds toward side 50a and side 50b of mesa 50, and proceeds toward side 50c, side 50d, side 50e, and side 50f of mesa 50. Substrate 40 is removed from chip 53 by the wet etching. Mesa 50 has no side perpendicular to the [01-1] direction and no side perpendicular to the [0-11] direction. A residue along the side, such as residue 40e of FIG. 11B, is less likely to occur. After the wet etching, etching stop layer 42 and semiconductor layer 44 remain on substrate 10.

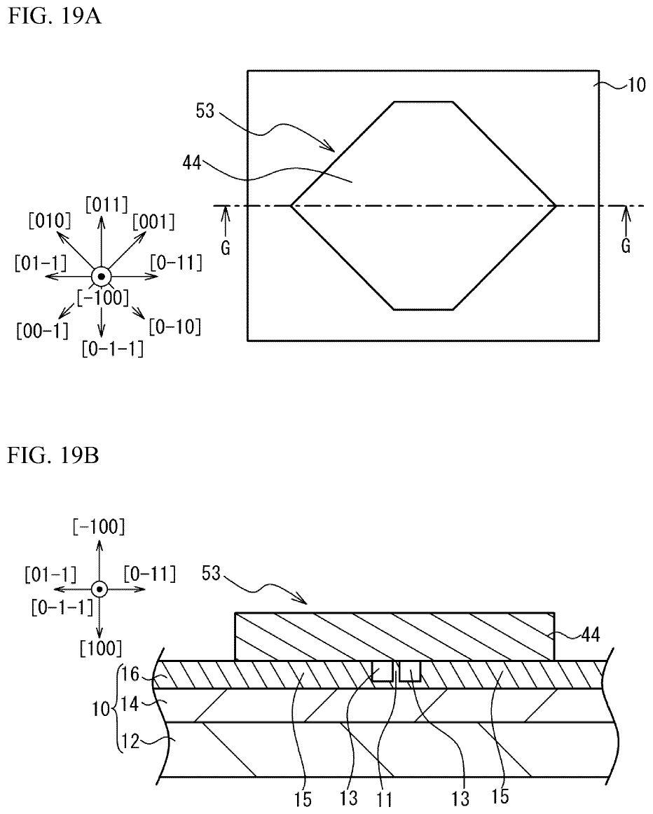

As illustrated in FIGS. 19A and 19B, etching stop layer 42 is removed by, for example, wet etching. The subsequent steps are performed on semiconductor layer 44 to form semiconductor device 20 illustrated in FIGS. 1A and 1B.

According to the second embodiment, mesa 50 includes etching stop layer 42 and semiconductor layer 44. Mesa 50 has no side perpendicular to the [01-1] direction and no side perpendicular to the [0-11] direction. Occurrence of the residues is suppressed in the wet etching of substrate 40.

As illustrated in FIG. 17A, a planar shape of chip 53 is rectangular. A planar shape of mesa 50 is hexagonal. Mesa 50 has sides inclined from the direction and the [0-1-1] direction. Specifically, mesa 50 has side 50c perpendicular to the direction, side 50d perpendicular to the [00-1] direction, side 50e perpendicular to the [0-10] direction, and side 50f perpendicular to the direction. Between side 50c and side 50d, and between side 50e and side 50f, wet etching of substrate 40 proceeds along the direction and the [0-1-1] direction. The etching rate in these directions is higher than the etching rate in other directions. Substrate 40 is removed by the wet etching. It is possible to suppress the influence of residue 40e on the manufacturing of semiconductor optical device 100.

The distance L7 from vertex 50g to side 40c and distance L7 from vertex 50h to side 40d of mesa 50 are equal to or less than 500 μm, and may be 0. That is, vertex 50g may overlap side 40c. Vertex 50h may overlap side 40d. That is, the lengths of the [01-1] direction and the [0-11] direction of mesa 50 are equal to or less than the length of substrate 40, and may be equal to the length of substrate 40 or may be less than the length of substrate 40.

An angle of each of vertex 50g between sides 50f and 50e and vertex 50h between sides 50c and 50d is from 60° to 120°, for example. The angle may be 70° or more, 80° or more, 110° or less, or 100° or less. Vertex 50g and vertex 50h may have a pointed shape or may include a curved line. A shape of mesa can be changed according to the shape of mask. The planar shape of mesa may be a polygonal shape other than a hexagonal shape, or may be a shape including a curved line.

### (First Modification)

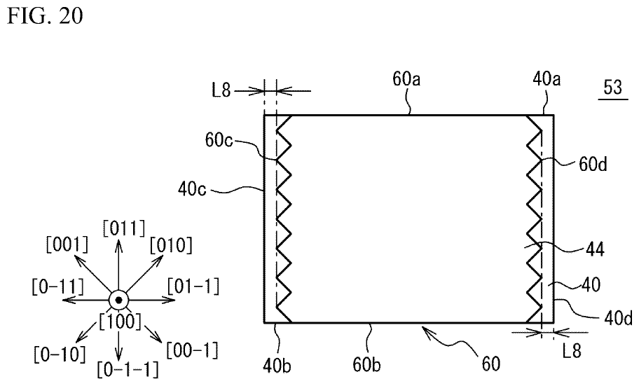

FIG. 20 is a plan view illustrating chip 53 according to a first modification. Description of the same configurations as that of the first embodiment and the second embodiment is omitted. A mesa 60 is provided in chip 53. Mesa 60 is formed by a portion of substrate 40, etching stop layer 42, and semiconductor layer 44, in the same manner as mesa 50. A planar shape of mesa 60 is a polygonal shape. A side 60a of mesa 60 is perpendicular to the direction and overlaps side 40a of substrate 40. A side 60b of mesa 60 is perpendicular to the [0-1-1] direction and overlaps side 40b of substrate 40.

Mesa 60 includes a plurality of vertices 60c and a plurality of vertices 60d. The plurality of vertices 60c face side 40c of substrate 40. The plurality of vertices 60c are arranged in the direction and the [0-1-1] direction. The plurality of vertices 60d face side 40d of substrate 40. The plurality of vertices 60d are arranged in the direction and the [0-1-1] direction. A distance L8 between side 40c and vertex 60c and a distance L8 between side 40d and vertex 60d are, for example, from 0 μm to 500 μm. A distance between two adjacent vertices 60c and a distance between two adjacent vertices 60d are, for example, from 50 μm to 500 μm. The angle of each of the vertices is, for example, from 60° to 120°. Each of the vertices may be pointed or rounded.

According to modification 1, wet etching proceeds to sides 40a and 40b, and also proceeds to both sides of vertex 60c and to both sides of vertex 60d, thereby suppressing occurrence of residues.

### (Second Modification)

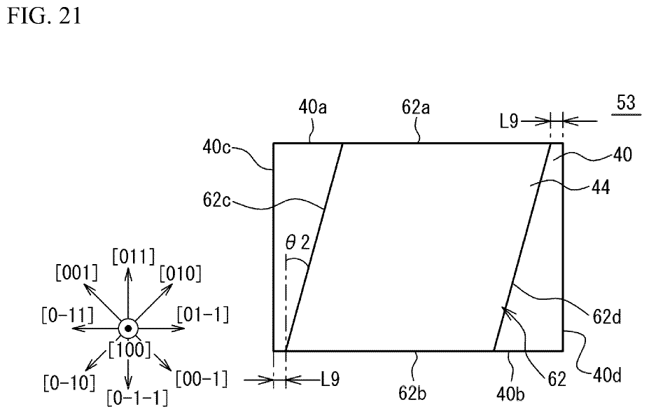

FIG. 21 is a plan view illustrating chip 53 according to a second modification. Description of the same configurations as that of the first embodiment and the second embodiment is omitted. A mesa 62 is provided in chip 53. A planar shape of mesa 62 is a parallelogram. A side 62a of mesa 62 is perpendicular to the direction and overlaps side 40a of substrate 40. A side 62b of mesa 62 is perpendicular to the [0-1-1] direction and overlaps side 40b of substrate 40.

A side 62c of mesa 62 faces side 40c of substrate 40. A side 62d faces side 40d. Side 62c and side 62d are inclined from the direction and the [0-1-1] direction. An inclination angle θ2 is, for example, 45° or less. A shortest distance L9 between side 40c and side 62c and a shortest distance between side 40d and side 62d are, for example, from 0 μm to 500 μm.

According to the second modification, etching of substrate 40 easily proceeds between side 62c and side 62b. The etching of substrate 40 easily proceeds between side 62d and side 62a. Occurrence of the etching residues is suppressed.

### (Third Modification)

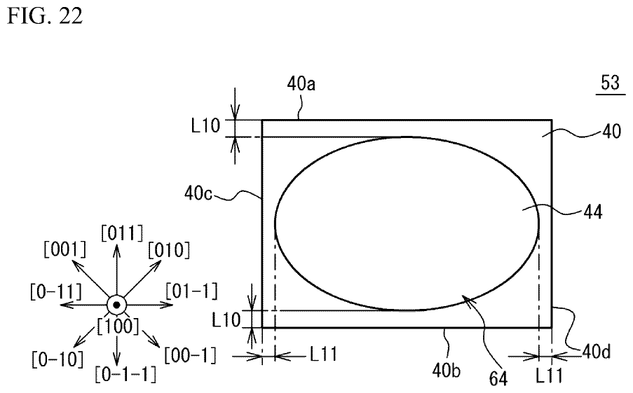

FIG. 22 is a plan view illustrating chip 53 according to a third modification. Description of the same configurations as that of the first embodiment and the second embodiment is omitted. A mesa 64 is provided in chip 53. A planar shape of mesa 64 is elliptical. The short axis of mesa 64 is parallel to the direction and the [0-1-1] direction. The long axis of mesa 64 is parallel to the [0-11] direction and the [01-1] direction. A shortest distance L10 between side 40a and mesa 64 and a shortest distance L10 between side 40b and mesa 64 are, for example, from 0 μm to 500 μm. A shortest distance L11 between side 40c and mesa 64 and a shortest distance L11 between side 40d and mesa 64 are, for example, from 0 μm to 500 μm. According to the third modification, etching proceeds to the end of mesa 64, thereby suppressing occurrence of residue.

Although the embodiments of the present disclosure have been described in detail above, the present disclosure is not limited to the specific embodiments, and various modifications and changes can be made within the scope of the gist of the present disclosure described in the claims.

What is claimed is:

1. A method of manufacturing a semiconductor optical device having a first substrate and a chip including a III-V compound semiconductor, the method comprising:
forming a first semiconductor layer on a second substrate;
forming a second semiconductor layer on the first semiconductor layer;
forming, on the second substrate, a mesa including a portion of the second semiconductor layer;
cutting the second substrate to form a chip including the mesa and the second substrate;
bonding the mesa of the chip to the first substrate;
after the bonding, removing the second substrate by etching; and
after the removing the second substrate, removing the first semiconductor layer,
wherein the etching in the removing the second substrate proceeds more easily in a second direction crossing a first direction than in the first direction, and
after the cutting, a length of the mesa in the first direction is equal to or less than a length of the second substrate in the first direction.

2. The method of manufacturing a semiconductor optical device according to claim 1, wherein, in the forming the mesa, the mesa including the portion of the second semiconductor layer is formed by etching another portion of the second semiconductor layer other than the portion of the second semiconductor layer, and
after the cutting, the length of the mesa in the first direction is smaller than the length of each of the second substrate and the first semiconductor layer in the first direction.

3. The method of manufacturing a semiconductor optical device according to claim 2, wherein a length between an end of the second substrate and an end of the mesa in the first direction is 1.5 times to 2 times a thickness of the second substrate.

4. The method of manufacturing a semiconductor optical device according to claim 2, wherein the second substrate and the mesa after the cutting have a side perpendicular to the first direction and a side perpendicular to the second direction.

5. The method of manufacturing a semiconductor optical device according to claim 1, wherein, in the forming the mesa, the mesa including a portion of the first semiconductor layer and the portion of the second semiconductor layer is formed by etching another portion of the first semiconductor layer and another portion of the second semiconductor layer other than the portion of the first semiconductor layer and the portion of the second semiconductor layer, and
the mesa has no side perpendicular to the first direction.

6. The method of manufacturing a semiconductor optical device according to claim 5, wherein a planar shape of the mesa is a polygonal shape or a shape including a curved line.

7. The method of manufacturing a semiconductor optical device according to claim 5, wherein the mesa has a side inclined from the second direction.

8. The method of manufacturing a semiconductor optical device according to claim 1, wherein the second substrate includes indium phosphide, and
the first semiconductor layer includes indium gallium arsenide.

9. The method of manufacturing a semiconductor optical device according to claim 8, wherein, in the removing the second substrate, the second substrate is removed by wet etching using hydrochloric acid as an etchant.

10. The method of manufacturing a semiconductor optical device according to claim 1, the method comprising, after the removing the first semiconductor layer, etching the portion of the second semiconductor layer.
